(19) United States
(12) Patent Application Publication
(10) Pub. No.: US 2011/0267893 A1
(43) Pub. Date: Nov. 3, 2011

(54) NON-VOLATILE SEMICONDUCTOR MEMORY AND MEMORY SYSTEM

(75) Inventors: Junichi KATO, Kyoto (JP); Hideto Kotani, Osaka (JP)

(73) Assignee: PANASONIC CORPORATION, Osaka (JP)

(21) Appl. No.: 13/180,148

(22) Filed: Jul. 11, 2011

Related U.S. Application Data
(63) Continuation of application No. PCT/JP2009/004755, filed on Sep. 18, 2009.

(30) Foreign Application Priority Data
Jan. 13, 2009 (JP) 2009-004577

(51) Int. Cl. G11C 16/34

(52) U.S. Cl. 365/185.22

(57) ABSTRACT

A non-volatile semiconductor memory determines that a given memory cell in an array is at a predetermined threshold voltage in a determination circuit by comparing a current of the memory cell with a reference current in a sense amplifier circuit. A reference current generation circuit includes a current variable device adjusting the reference current. A current adjustment amount calculator receives address information of the memory cell of which threshold voltage is determined and calculates a current adjustment amount corresponding to the address information. The current variable device adjusts the reference current based on the calculated current adjustment amount. Therefore, even when characteristics of interconnects coupled to the sense amplifier circuit, the target memory cell, and the sense amplifier vary, an offset amount between an actual threshold and an apparent threshold is eliminated to reduce electric stress applied to the memory cell in a rewrite operation.

### CROSS-REFERENCE TO RELATED APPLICATION

This is a continuation of PCT International Application PCT/JP2009/004755 filed on Sep. 18, 2009, which claims priority to Japanese Patent Application No. 2009-004577 filed on Jan. 13, 2009. The disclosures of these applications including the specifications, the drawings, and the claims are hereby incorporated by reference in their entirety.

### BACKGROUND

The present disclosure relates to non-volatile semiconductor memories such as flash memories, and more particularly to memories recording information by changing the thresholds of memory cells in rewriting the information and to modification of verify circuits detecting the change of the thresholds when changing the thresholds.

In a conventional flash memory, in a flash memory of e.g., Japanese Patent Publication No. 2003-109389, the threshold of a transistor, which is called “memory cell” and is a minimum unit of information storage, is changed in recording information or rewriting information. Therefore, a rewrite operation of information needs to be set to meet necessary threshold conditions. Table 1 shows an example of a conventional relationship between storage information of such a flash memory and a threshold of a memory cell.

TABLE 1

| Mode | Threshold |
|---|---|
| Erase (Data “1”) | 4 V or less |
| Write (Data “0”) | 6 V or more |

In the table 1, a memory cell is in an erase mode using data “1” as recorded information, and the threshold of the memory cell is 4 V or less at this time. On the other hand, data “0” is a result of a write operation, and is obtained by electrically increasing the threshold of the memory cell in an erase mode to 6 V or more. Note that, these voltage values are examples and are not uniquely determined. In the example of the table 1, the difference between thresholds in the erase mode and the write mode is 2 V or more, which is a margin for holding information in a mode other than a rewrite mode. By setting the margin, accurate information can be read even when the information is left for a long period or a read mode has continued.

In a rewrite operation, the so-called verify operation is performed to confirm that a memory cell to be rewritten has a predetermined threshold (6 V or more in a write mode, and 4 V or less in an erase mode in the example of the table 1). The verify operation is performed by a verify circuit. FIG. 3 is a schematic view of the verify circuit.

In FIG. 3, a source of a transistor 1 functions as a memory cell is coupled to the bit line 2. A gate of the memory cell transistor 1 is coupled to a word line 3. The bit line 2 is eventually coupled to a sense amplifier 4. The sense amplifier 4 is coupled to a reference current output circuit 5 which is separately prepared. When a current flows to the bit line 2, the current is compared to an output current from the reference current output circuit 5 to perform determination of information.

FIG. 4 illustrates a circuit corresponding to the reference current generation circuit 5 of FIG. 3 and being a reference transistor. In FIG. 4, the reference current generation circuit 5 of FIG. 3 is implemented by a reference cell 6 and a voltage generation circuit 7.

In FIGS. 3 and 4, a single reference current generation circuit 5 and a single sense amplifier 4 are prepared for a single memory cell 1. Actually, the memory cell 1 is provided in an array. One of a plurality of bit lines 2 coupled to the array is selected and coupled to the sense amplifier 4. In general, a plurality of reference current generation circuits 5 and a plurality of sense amplifiers 4 are prepared and operate in parallel.

### SUMMARY

However, in the verify circuit of the conventional flash memory, when outputting data in comparison to a reference current, an output result does not necessarily correspond to the threshold of the selected memory cell transistor 1, and varies depending on causes other than electrical characteristics of the memory cell transistor 1. FIGS. 9, 10, and 11 are examples showing the variations.

FIG. 9 illustrates three cases of a relationship between a current generated by a memory cell in verification and a signal output from a sense amplifier in accordance with the current. The example of the figure shows that output results differ depending on selected sectors. The output of the sense amplifier is characterized in that the output is inverted using a constant value as a threshold with respect to a memory cell current received as an input. At this time, memory cell currents corresponding to rising of a sense amplifier output differ depending on sectors including the selected memory cell. The difference occurs since electric capacitance (capacitance) of a bit line coupled to a memory cell differs depending on a selected sector. Due to the bit line capacitance, even when a current flows from a memory cell, delay occurs until the current reaches a sense amplifier. The delay time differs depending on the magnitude of the capacitance. Thus, in conditions in which bit line capacitance is different depending on, for example, the selected sector, a difference occurs in the output of the sense amplifier.

FIG. 10 illustrates that output results of a sense amplifier differ depending on the physical location of a memory cell. The example of the figure shows that the physical location of the memory cell is at the end of a memory cell array, and in the center. Since the end and the center of the memory cell have different length until the bit line reaches the sense amplifier, a current amount decreases due to resistance of the bit line. With respect to a word line, since the length of the word line differs depending on the physical location of the memory cell, a voltage applied to a gate differs due to a difference in the length until the memory cell reaches the gate. As a result, depending on the physical location of the memory cell, memory cell currents corresponding to rising of the sense amplifier output differ.

FIG. 11 illustrates that output results of a sense amplifier differ depending on the sense amplifier. In general, a flash memory includes a plurality of sense amplifier circuits, which operate in parallel. However, sense amplifiers themselves show circuit variations, which cause a difference in current amounts in rising of outputs with respect to a same input current in the plurality of sense amplifiers manufactured in a same process.

Once a difference in output results occurs with respect to the same current amount, loads to a memory cell occurring in a rewrite operation differ. FIG. 5 illustrates the difference of the loads. The figure shows apparent thresholds of three memory cells A, B, and C obtained from the determination result of the sense amplifier in write and erase modes. The figure also shows thresholds of the memory cells A, B, and C in write and erase modes based on actual electrical characteristics. With respect to the apparent thresholds of FIG. 5, the memory cell A, the memory cell B, and the memory cell C have equal thresholds. This is because a same sense amplifier is used for determining whether a voltage reaches a threshold in write and erase operations. On the other hand, FIG. 6 illustrates that the memory cell A, the memory cell B, and the memory cell C have different thresholds. This is because the outputs of the sense amplifier differ depending on the selected sector, the physical location of the memory cell, and the used sense amplifier, as shown in FIGS. 9, 10, and 11. At this time, the memory cell B has a higher threshold than the memory cell A after a write operation. The memory cell B is required to reach a higher threshold than the memory cell A in each write operation. As a result, greater electric stress is applied to the memory cell B than to the memory cell A in a write operation. The memory cell C is set to have a lower threshold than the memory cell A. In this case, the memory cell C is required to reach a lower threshold than the memory cell A in an erase operation. As a result, greater electric stress is applied to the memory cell C than to the memory cell A in an erase operation.

When greater electric stress is applied in writing and erase operations, rewrite resistance and data retention capability deteriorates. FIG. 8 illustrates a relationship between an offset amount between an actual threshold and an apparent threshold, and data retention characteristics. When the difference between the apparent threshold and the actual threshold increases in a positive direction or a negative direction, data retention characteristics deteriorate.

It is an objective of the present invention to eliminate a difference between an apparent threshold of a memory cell, which is determined by a sense amplifier, and an actual threshold of the memory cell to reduce electric stress applied to the memory cell in a rewrite operation, and to improve rewrite resistance and data retention characteristics.

In order to achieve the objective, in the present disclosure, a sense amplifier output is corrected by a difference between an apparent threshold of a memory cell and an actual threshold of the memory cell. The correction of the sense amplifier output is made by adjusting a reference current which is compared to a memory cell current.

Specifically, a non-volatile semiconductor memory of the present disclosure includes a determination circuit determining that a given memory cell in an array is in a predetermined mode by comparing a current of the memory cell with a reference current. A reference current generation circuit generating the reference current includes a current amount variable circuit. The current amount variable circuit receives a current variable amount signal from a current variable amount calculation circuit. The current variable amount calculation circuit receives an address signal of a memory cell in an array, which is subjected to determination by the determination circuit, sets the current variable amount signal varying a current amount of the reference current in accordance with the address signal, and outputs the current variable amount signal to the current amount variable circuit.

In the non-volatile semiconductor memory according to the present disclosure, when determining that a memory cell subjected to a write or erase operation is in a predetermined mode after the write or erase operation by comparing the current of the memory cell to the reference current in the determination circuit, the current variable amount calculation circuit outputs the current variable amount signal corresponding to the address signal to the current amount variable circuit to vary the reference current used in the determination circuit.

In the non-volatile semiconductor memory according to the present disclosure, when determining a mode of the memory cell at an address to be read in a read operation by comparing the current of the memory cell to the reference current in the determination circuit, the current variable amount calculation circuit outputs the current variable amount signal corresponding to the address signal to the current amount variable circuit to vary the reference current used in the determination circuit.

In the non-volatile semiconductor memory according to the present disclosure, the current variable amount calculation circuit includes a logic circuit receiving the address signal and converting the address signal to the current variable amount signal.

In the non-volatile semiconductor memory according to the present disclosure, the current variable amount calculation circuit receives the address signal, and refers to a conversion table set in the memory in advance when outputting the current variable amount signal in accordance with the address signal.

In the non-volatile semiconductor memory according to the present disclosure, the conversion table set in the memory in advance includes a recordable non-volatile memory, and is provided independently from a single body of the non-volatile memory.

In the non-volatile semiconductor memory according to the present disclosure, the current variable amount calculation circuit obtains the received address signal and information of the number of rewrite operations, which is recorded in the memory in advance, and calculates the current variable amount in accordance with the address signal and the information of the number of the rewrite operations.

A memory system according to the present disclosure includes the non-volatile semiconductor memory; and an external controller controlling the non-volatile memory. The external controller controls a current variable amount calculation circuit in the non-volatile semiconductor memory with a control signal or a specific control sequence.

A non-volatile semiconductor memory according to the present disclosure includes a determination circuit determining that a given memory cell in an array is in a predetermined mode by comparing the mode of the given memory cell to a mode of a reference cell. A gate of the reference cell is electrically coupled to a voltage generation circuit. The voltage generation circuit receives voltage adjustment amount information from a voltage adjustment amount calculation circuit. The voltage adjustment amount calculation circuit receives an address signal of a memory cell in an array, which is subjected to determination by the determination circuit, sets the voltage adjustment amount information changing a gate voltage of the reference cell in accordance with the address signal, and outputs the voltage adjustment amount information to the voltage generation circuit.

In the non-volatile semiconductor memory according to the present disclosure, when determining that a memory cell subjected to a write or erase operation is in a predetermined mode after the write or erase operation by comparing the mode of the memory cell to the mode of the reference cell in the determination circuit, the voltage adjustment amount calculation circuit outputs voltage adjustment amount information corresponding to the address signal to the voltage generation circuit to change the mode of the reference cell used in the determination circuit.

In the non-volatile semiconductor memory according to the present disclosure, when determining a mode of the memory cell at an address to be read in a read operation by comparing the mode of the memory cell to the mode of the reference cell in the determination circuit, the voltage adjustment amount calculation circuit outputs current adjustment amount information corresponding to the address signal to the voltage generation circuit to change the mode of the reference cell used in the determination circuit.

In the non-volatile semiconductor memory according to the present disclosure, the voltage adjustment amount calculation circuit includes a logic circuit receiving the address signal and converting the address signal to the voltage adjustment amount information.

In the non-volatile semiconductor memory according to the present disclosure, the voltage adjustment amount calculation circuit receives the address signal, and refers to a conversion table set in the memory in advance when outputting the voltage adjustment amount information in accordance with the address signal.

In the non-volatile semiconductor memory according to the present disclosure, the conversion table set in the memory in advance includes a recordable non-volatile memory, and is provided independently from a single body of the non-volatile memory.

In the non-volatile semiconductor memory according to the present disclosure, the voltage adjustment amount calculation circuit obtains the received address signal and information of the number of rewrite operations, which is recorded in the memory in advance, and calculates the voltage adjustment amount information in accordance with the address signal and the information of the number of the rewrite operations.

A memory system according to the present disclosure includes the non-volatile semiconductor memory; and an external controller controlling the non-volatile memory. The external controller controls the voltage adjustment amount calculation circuit in the non-volatile semiconductor memory with a control signal or a specific control sequence.

In the non-volatile semiconductor memory according to the present disclosure, the predetermined mode of the memory cell is a predetermined threshold voltage.

As described above, in the non-volatile semiconductor memory according to the present disclosure, the current variable amount calculation circuit calculates the current variable amount in accordance with the address of the memory cell of which threshold is determined. In accordance with the calculated current variable amount, the reference current which is compared to the memory cell current is adjusted, and the sense amplifier output is corrected in accordance with the address. As a result, a difference between an apparent threshold of the memory cell and an actual threshold of the memory cell decreases, thereby reducing electric stress applied to the memory cell in a rewrite operation, and improving rewrite resistance and data retention characteristics.

FIG. 13 illustrates that sense amplifier outputs of the memory cell A, the memory cell B, and the memory cell C shown in FIG. 6 are corrected to unify the actual thresholds of the memory cells. When FIG. 13 is more specifically described, the apparent threshold of the memory cell B is corrected to close to the threshold of the memory cell A by reducing the reference current. Similarly, with respect to the memory cell C, the output of the sense amplifier can be corrected by increasing the reference current.

As described above, according to the non-volatile semiconductor memory of the present disclosure, the reference current which is compared to the memory cell current is variable in accordance with the address of the memory cell of which threshold is determined, the difference between an apparent threshold of the memory cell and an actual threshold of the memory cell decreases to reduce electric stress applied to the memory cell in a rewrite operation and to improve rewrite resistance and data retention characteristics.

### BRIEF DESCRIPTION OF THE DRAWINGS

FIG. 1 illustrates a verify circuit which is an important part of a non-volatile semiconductor memory according to a first embodiment of the present disclosure.

FIG. 2 illustrates a verify circuit which is an important part of a non-volatile semiconductor memory according to a second embodiment of the present disclosure.

FIG. 3 illustrates a conventional verify circuit.

FIG. 4 illustrates another conventional verify circuit.

FIG. 5 illustrates thresholds of memory cells in write and erase modes obtained from determination results of a sense amplifier.

FIG. 6 illustrates actual thresholds of memory cells in write and erase modes.

FIG. 7 illustrates a flow of verification in an embodiment of the present disclosure.

FIG. 8 illustrates a relationship between an offset amount and data retention characteristics.

FIG. 9 illustrates a difference in sense amplifier outputs due to a difference in sectors.

FIG. 10 illustrates a difference in sense amplifier outputs due to a difference in physical locations of a memory cell.

FIG. 11 illustrates a difference in sense amplifier outputs due to a difference in sense amplifiers.

FIG. 12 illustrates a configuration of an array effect correction table.

FIG. 13 illustrates a reference current correction method for solving a problem of conventional technique.

FIG. 14 illustrates a configuration of a memory system including an externally controllable current amount correction calculator.

FIG. 15 illustrates an example configuration of a reference current generation circuit included in a non-volatile semiconductor memory according to an embodiment of the present disclosure.

### DETAILED DESCRIPTION

Embodiments of the present disclosure will be described hereinafter with reference to the drawings.

### First Embodiment

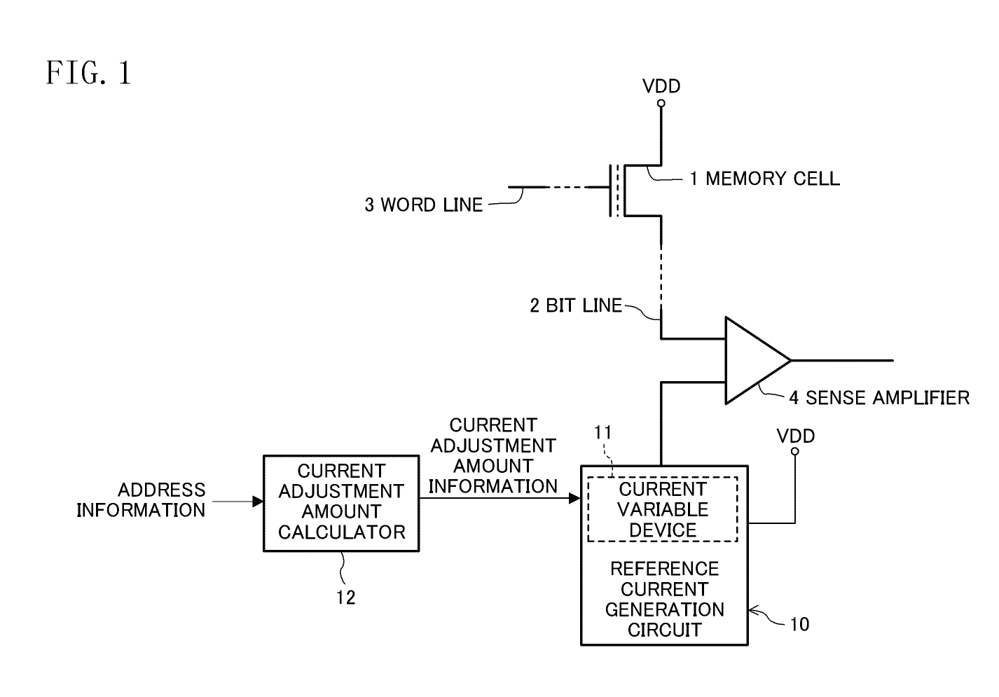

FIG. 1 illustrates a non-volatile semiconductor memory according to a first embodiment of the present disclosure.

In the figure, a source of a transistor 1, which functions as a memory cell, is coupled to a bit line 2. A gate of the memory cell transistor 1 is coupled to a word line 3. The bit line 2 is eventually coupled to a sense amplifier (determination circuit) 4. The sense amplifier 4 is coupled to a reference current generation circuit 10. When a current flows to the bit line 2, the current is compared to an output current from the reference current generation circuit 10 to perform determination of information.

In FIG. 1, a current variable device (current amount variable circuit) 11 is provided inside the reference current generation circuit 10 to change an output of a reference current. The current variable device 11 sets a current change amount of a reference current in accordance with an address of a memory cell to be operated. In order to set the current change amount in accordance with an address, a current adjustment amount calculator (current variable amount calculation circuit) 12 is provided and the current variable device 11 adjusts a reference current amount based on the calculation result. The current adjustment amount calculator 12 receives address information of the memory cell to be operated as input information, determines an appropriate current adjustment amount by calculation, and transmits the current adjustment amount information (a current variable amount signal) to the current variable device 11.

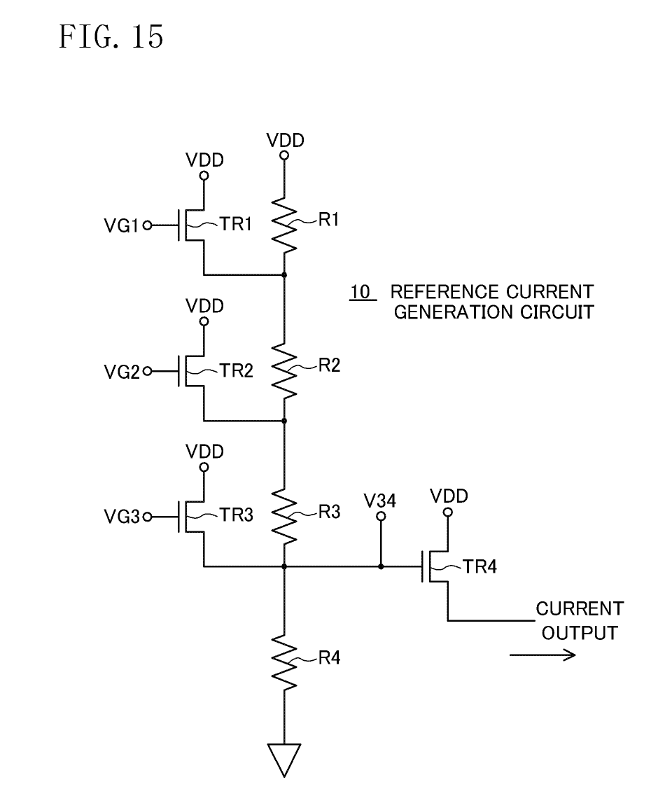

The reference current generation circuit 10 shown in FIG. 1 is implemented by a circuit configuration shown in FIG. 15. In FIG. 15, four resistors R1, R2, R3 and R4 are coupled in series from a power source VDD to ground. Current amounts are controlled by three transistors TR1, TR2, and TR3. Drains of the transistors TR1-TR3 are coupled between the resistor R1 and the resistor R2, between the resistor R2 and the resistor R3, and between the resistor R3 and the resistor R4. A voltage V34 between the resistor R3 and the resistor R4 changes depending on an ON state or an OFF state of the three transistors TR1-TR3. The voltage V34 between the resistor R3 and the resistor R4 is coupled to a gate of the transistor TR4, and a drain current of the transistor TR4 serves as a reference current.

With this configuration, a reference current corresponding to an address can be provided, and an output result of the sense amplifier 4 can be close to a result corresponding to an actual threshold voltage (mode) of the memory cell 1.

The adjustment amount calculator (current variable amount calculation circuit) 12 is implemented by creating a truth table shown in Table 2 and forming a logic gate circuit corresponding to the truth table. In the truth table of Table 2, a value a is output when input address information is within the range of 0x001000-0x001fff, a value b is output when the information is within the range of 0x002000-0x002fff, and a value c is output when the information is within the range of 0x003000-0x003fff.

TABLE 2

| Input (Address Information, in Hex Notation) | Output (Current |
|---|---|
| X indicates “Don't Care” | Adjustment Amount) |
| 001xxx | a |
| 002xxx | b |
| 003xxx | c |
| . . . | . . . |

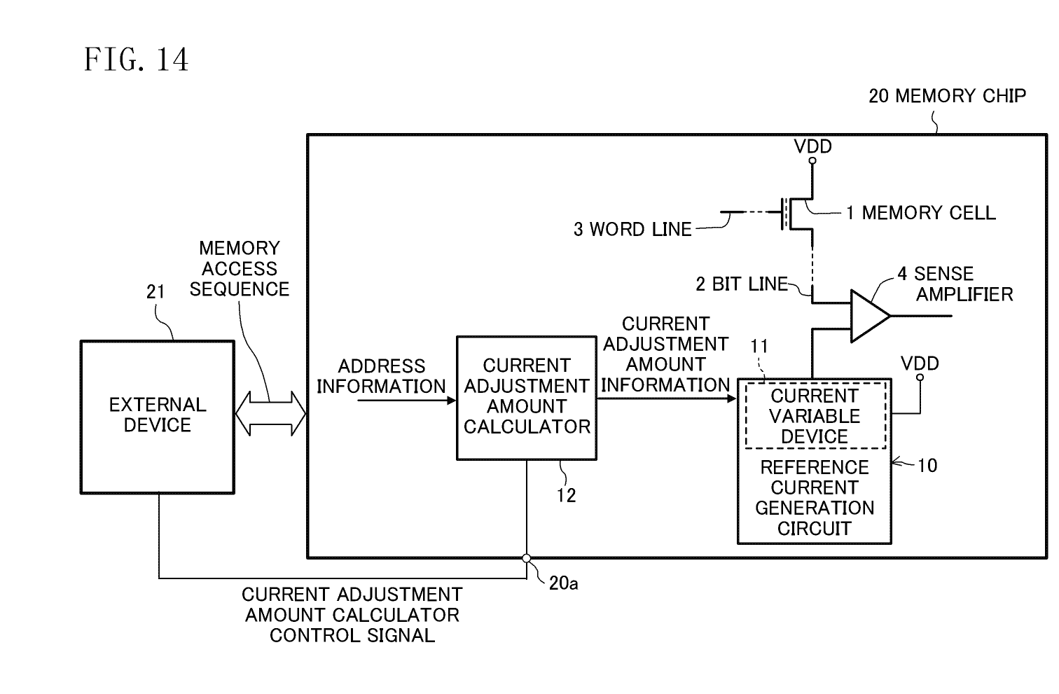

FIG. 14 illustrates a configuration selecting whether or not calculation of the current adjustment amount calculator 12 in the non-volatile memory is performed in accordance with a device using the non-volatile memory shown in FIG. 1. FIG. 14 illustrates a memory system including a memory chip 20 and an external device (external controller) 21 using the memory chip 20. The memory chip 20 includes the non-volatile memory shown in FIG. 1 inside. In FIG. 14, the external device 21 enables a necessary memory access by performing a memory access sequence for the memory chip 20. In this embodiment, a signal terminal 20a for controlling the current adjustment amount calculator 12 within the memory chip 20 is provided as appropriate, and the current adjustment amount calculator 12 can be controlled from the external device 21 through the signal terminal 20a. While in FIG. 14, a control terminal 20a is separately provided to enable external control of the current adjustment amount calculator 12, the external control of the current adjustment amount calculator 12 can be included as a part of a specification of a memory access sequence.

### Second Embodiment

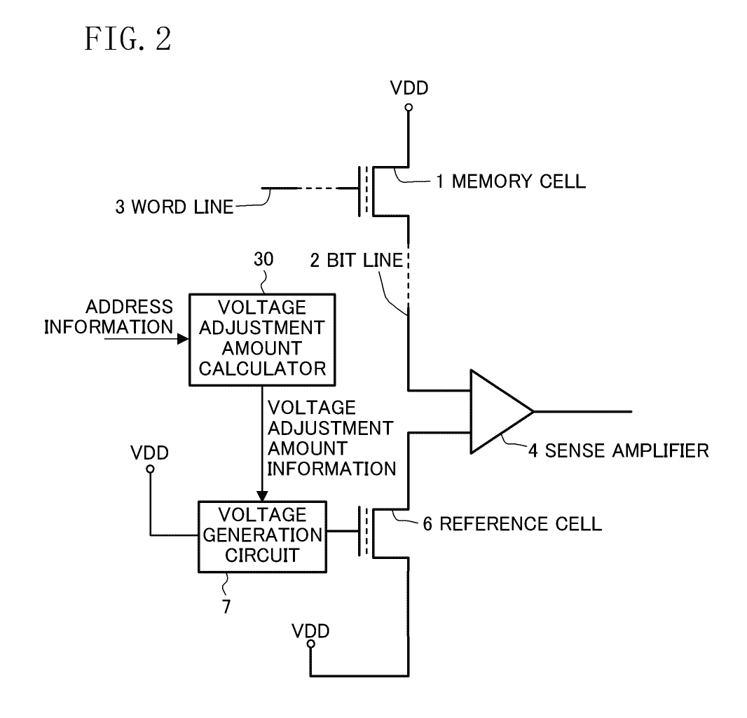

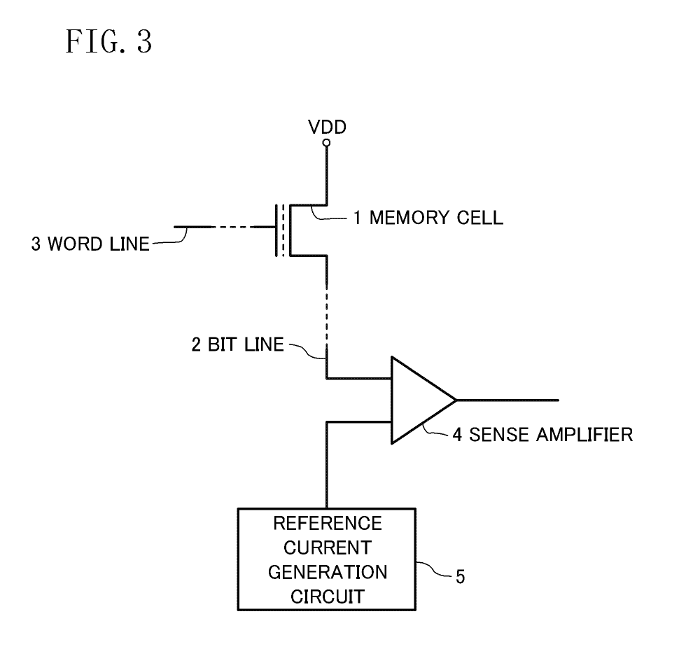

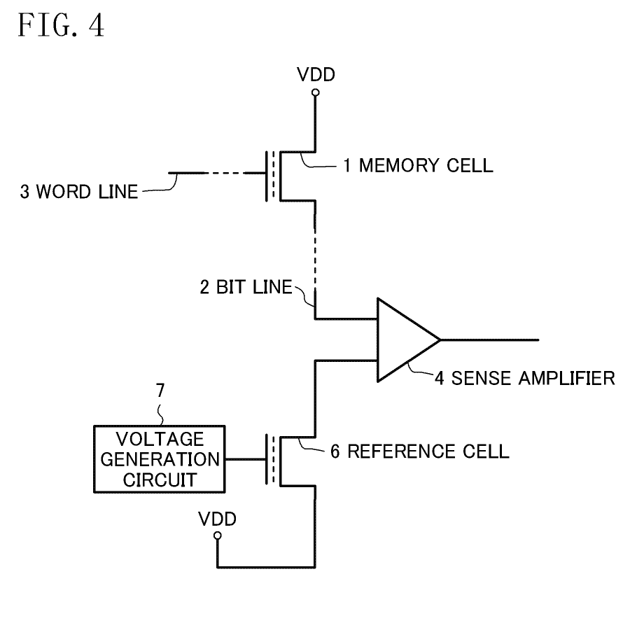

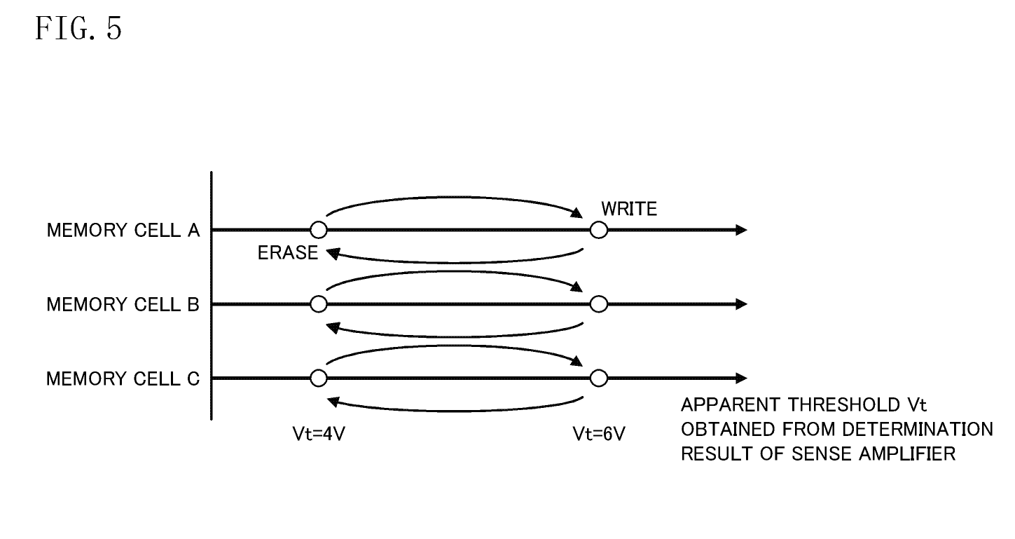

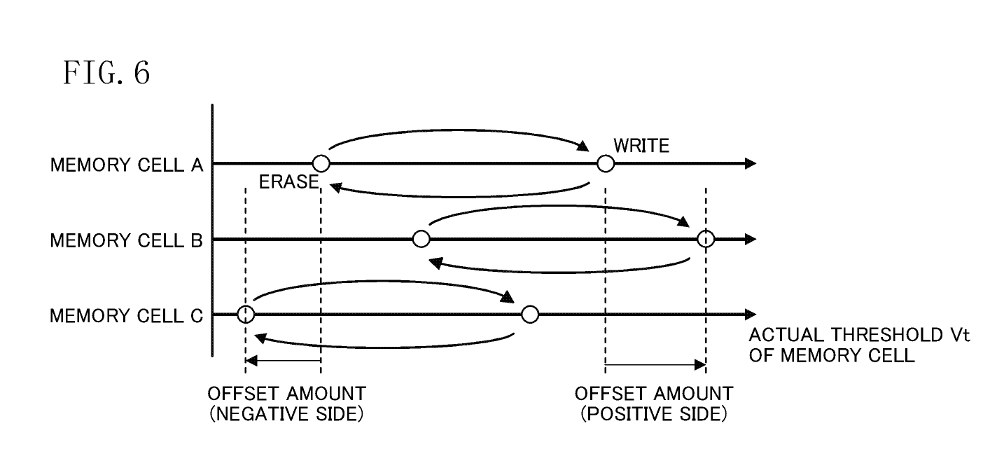

FIG. 2 illustrates a non-volatile semiconductor memory according to a second embodiment of the present disclosure. In this embodiment, the reference current generation circuit is implemented by a combination of the reference cell 6 and a voltage generation circuit 7. The voltage generation circuit 7 is coupled to the gate of the reference cell 6, and changes the reference current with its output voltage. The voltage generation circuit 7 receives voltage adjustment amount information from a voltage adjustment amount calculator (voltage adjustment amount calculation circuit) 30 separately provided, and outputs a predetermined voltage. The voltage adjustment amount calculator 30 receives address information of a memory cell to be operated as input information, determines an appropriate voltage adjustment amount by calculation, and transmits current adjustment amount information to the voltage generation circuit 7.

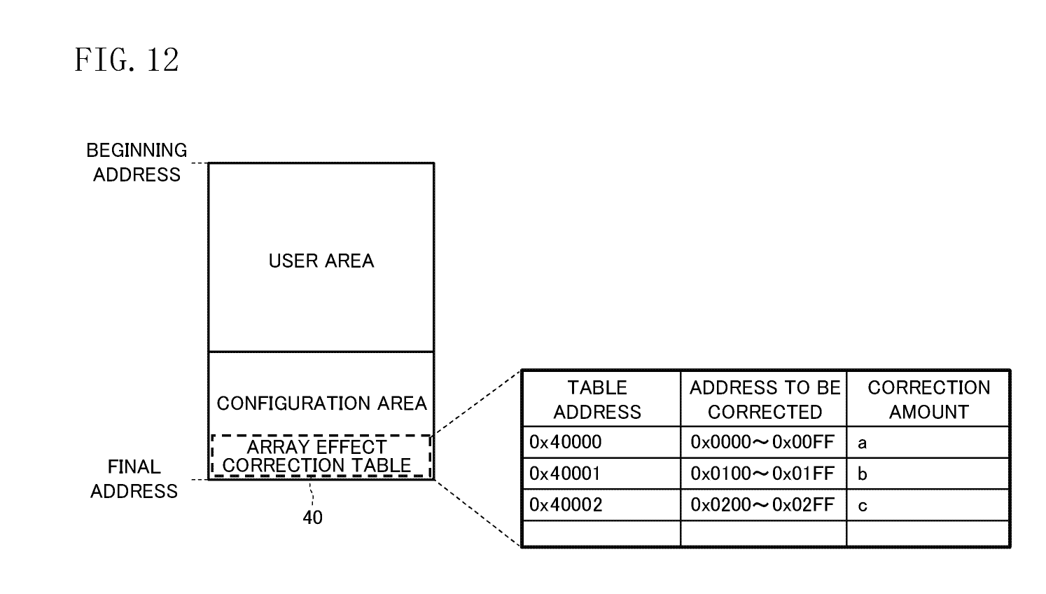

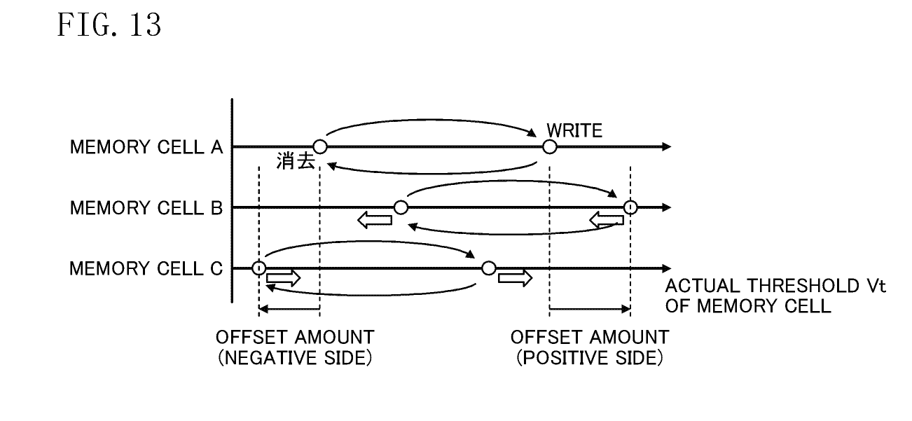

FIG. 12 illustrates a method of setting an appropriate current correction amount for this embodiment using a correction amount table. FIG. 12 is a memory map using logic addresses of a conventional flash memory. Addresses from a beginning address to a specific address are a user area used by a user, and the subsequent addresses are a configuration area storing individual values for setting hardware, etc. In this embodiment, an array effect correction table (conversion table) 40 is provided in a part of the configuration area. In the array effect correction table 40, an address to be corrected and the corresponding correction amount are stored at each table address. The voltage adjustment amount calculator 30 accesses to the correction table, and obtains correction amount information. Most preferably, in creation of the address table, characteristic data of a parameter depending on the address is obtained in testing, for example, and stored in the table. While in FIG. 12, a part of the flash memory is used for the correction table, a ROM or an electrical fuse may be used.

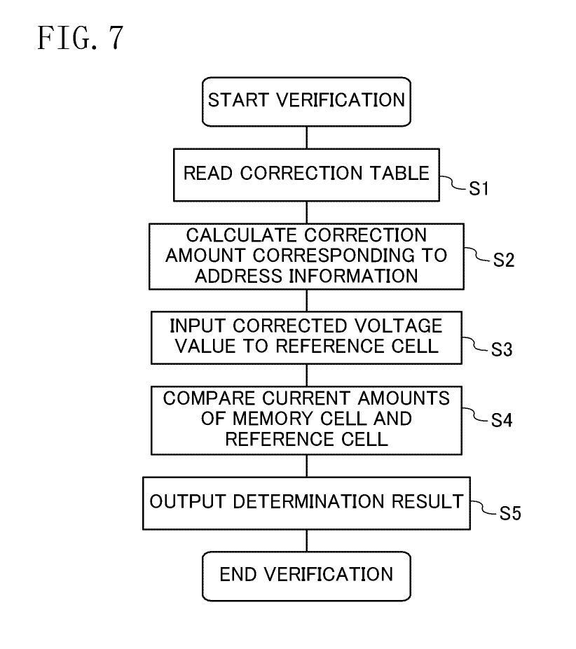

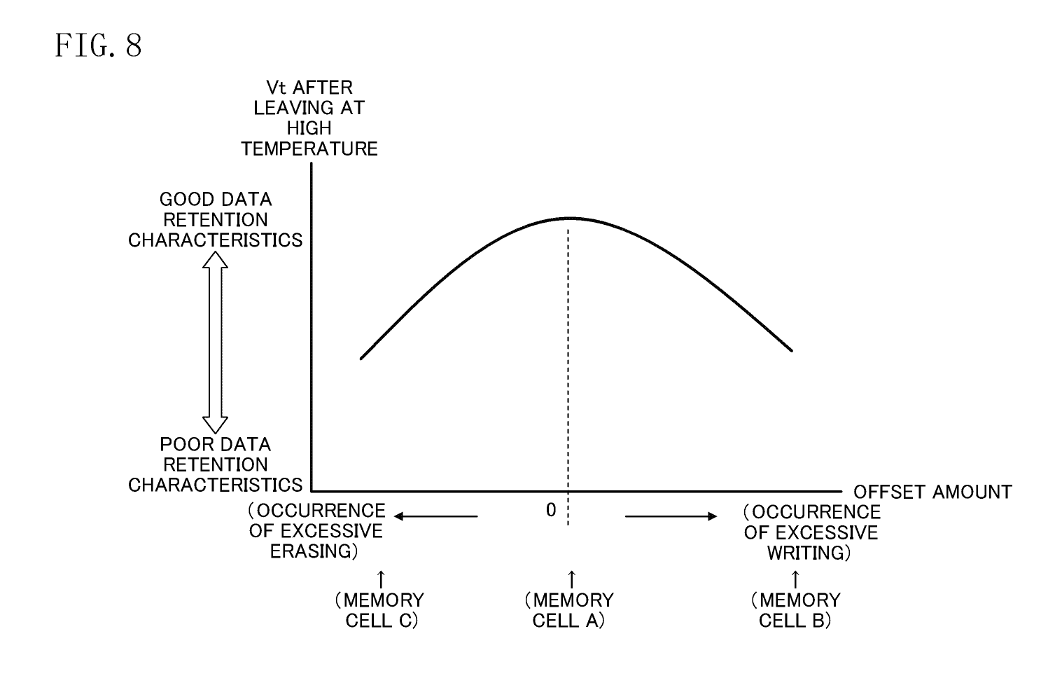

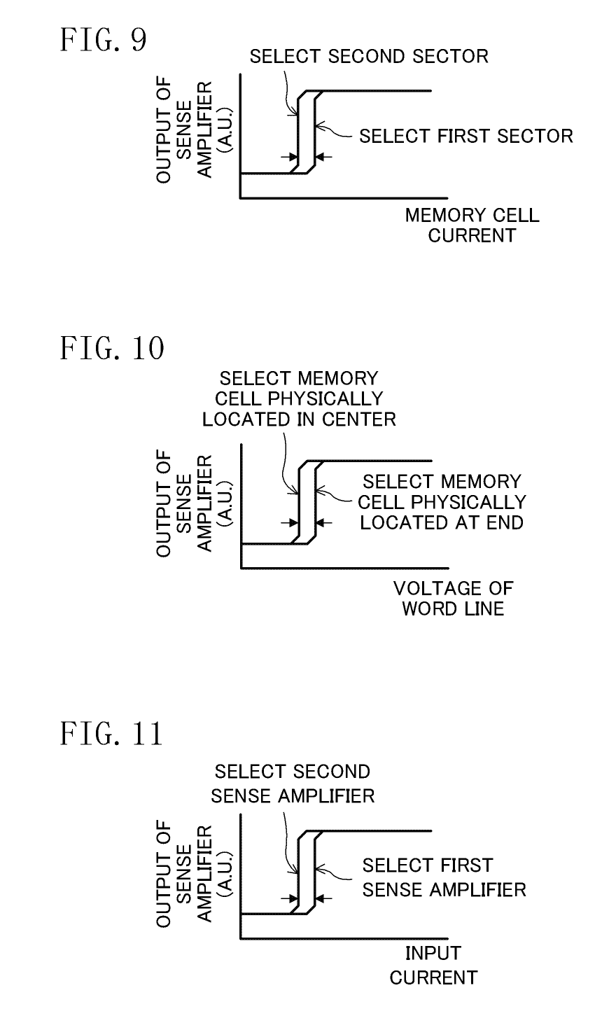

FIG. 7 illustrates a flow of appropriate verification in this embodiment. When verification starts, a correction table is accessed in step S1. Then, a correction amount corresponding to an address is calculated in step S2. In step S3, a voltage value corrected based on the calculated correction amount is input to the reference cell 6. In step S4, the sense amplifier 4 compares the current of the bit line 2 to the reference current flowing from the reference cell 6 to which the correction voltage value is input. The comparison result of the two currents is output in step S5. In accordance with the output result, it is determined whether or not a predetermined operation is repeated again. Verification is performed by the above-described flow.

With reference to FIG. 7, verification in a write or erase operation has been described. Similarly, in a read operation, the reference current can be changed in accordance with the address. By changing the reference current in accordance with the address in a read operation, a margin of a threshold which meets data retention specification can be set at each address to improve data retention characteristics.

Note that, FIG. 7 illustrates a flow of changing the reference current in accordance with the address. Not only address information, there is a method of changing the reference current using history information of the number of rewrite operations. It is known that data retention characteristics deteriorate as the number of rewrite operations increases. The information of the number of rewrite operations is treated as a parameter determining the reference current, thereby improving data retention characteristics.

As described above, the non-volatile semiconductor memory according to the present disclosure is mainly useful for conditions requiring resistance to a large number of rewrite operations or data retention for a long period.

What is claimed is:

1. A non-volatile semiconductor memory comprising
a determination circuit determining that a given memory cell in an array is in a predetermined mode by comparing a current of the memory cell with a reference current, wherein
a reference current generation circuit generating the reference current includes a current amount variable circuit,
the current amount variable circuit receives a current variable amount signal from a current variable amount calculation circuit, and
the current variable amount calculation circuit receives an address signal of a memory cell in an array, which is subjected to determination by the determination circuit, sets the current variable amount signal varying a current amount of the reference current in accordance with the address signal, and outputs the current variable amount signal to the current amount variable circuit.

2. The non-volatile semiconductor memory of claim 1, wherein
when determining that a memory cell subjected to a write or erase operation is in a predetermined mode after the write or erase operation by comparing the current of the memory cell to the reference current in the determination circuit,
the current variable amount calculation circuit outputs the current variable amount signal corresponding to the address signal to the current amount variable circuit to change the reference current used in the determination circuit.

3. The non-volatile semiconductor memory of claim 1, wherein
when determining a mode of the memory cell at an address to be read in a read operation by comparing the current of the memory cell to the reference current in the determination circuit,
the current variable amount calculation circuit outputs the current variable amount signal corresponding to the address signal to the current amount variable circuit to change the reference current used in the determination circuit.

4. The non-volatile semiconductor memory of claim 1, wherein
the current variable amount calculation circuit includes a logic circuit receiving the address signal and converting the address signal to the current variable amount signal.

5. The non-volatile semiconductor memory of claim 1, wherein
the current variable amount calculation circuit receives the address signal, and refers to a conversion table set in the memory in advance when outputting the current variable amount signal in accordance with the address signal.

6. The non-volatile semiconductor memory of claim 5, wherein
the conversion table set in the memory in advance includes a recordable non-volatile memory, and is provided independently from a single body of the non-volatile memory.

7. The non-volatile semiconductor memory of claim 1, wherein
the current variable amount calculation circuit obtains the received address signal and information of the number of rewrite operations, which is recorded in the memory in advance, and calculates the current variable amount in accordance with the address signal and the information of the number of the rewrite operations.

8. A memory system comprising:
the non-volatile semiconductor memory of claim 1; and
an external controller controlling the non-volatile memory, wherein
the external controller controls a current variable amount calculation circuit in the non-volatile semiconductor memory with a control signal or a specific control sequence.

9. A non-volatile semiconductor memory comprising
a determination circuit determining that a given memory cell in an array is in a predetermined mode by comparing the mode of the given memory cell to a mode of a reference cell, wherein
a gate of the reference cell is electrically coupled to a voltage generation circuit,
the voltage generation circuit receives voltage adjustment amount information from a voltage adjustment amount calculation circuit, and
the voltage adjustment amount calculation circuit receives an address signal of a memory cell in an array, which is subjected to determination by the determination circuit, sets the voltage adjustment amount information changing a gate voltage of the reference cell in accordance with the address signal, and outputs the voltage adjustment amount information to the voltage generation circuit.

10. The non-volatile semiconductor memory of claim 9, wherein
when determining that a memory cell subjected to a write or erase operation is in a predetermined mode after the write or erase operation by comparing the mode of the memory cell to the mode of the reference cell in the determination circuit,
the voltage adjustment amount calculation circuit outputs voltage adjustment amount information corresponding to the address signal to the voltage generation circuit to change the mode of the reference cell used in the determination circuit.

11. The non-volatile semiconductor memory of claim 9, wherein
when determining a mode of the memory cell at an address to be read in a read operation by comparing the mode of the memory cell to the mode of the reference cell in the determination circuit,
the voltage adjustment amount calculation circuit outputs current adjustment amount information corresponding to the address signal to the voltage generation circuit to change the mode of the reference cell used in the determination circuit.

12. The non-volatile semiconductor memory of claim 9, wherein
the voltage adjustment amount calculation circuit includes a logic circuit receiving the address signal and converting the address signal to the voltage adjustment amount information.

13. The non-volatile semiconductor memory of claim 9, wherein
the voltage adjustment amount calculation circuit receives the address signal, and refers to a conversion table set in the memory in advance when outputting the voltage adjustment amount information in accordance with the address signal.

14. The non-volatile semiconductor memory of claim 13, wherein
the conversion table set in the memory in advance includes a recordable non-volatile memory, and is provided independently from a single body of the non-volatile memory.

15. The non-volatile semiconductor memory of claim 9, wherein
the voltage adjustment amount calculation circuit obtains the received address signal and information of the number of rewrite operations, which is recorded in the memory in advance, and calculates the voltage adjustment amount information in accordance with the address signal and the information of the number of the rewrite operations.

16. A memory system comprising:
the non-volatile semiconductor memory of claim 9; and
an external controller controlling the non-volatile memory, wherein
the external controller controls the voltage adjustment amount calculation circuit in the non-volatile semiconductor memory with a control signal or a specific control sequence.

17. The non-volatile semiconductor memory of claim 1, wherein
the predetermined mode of the memory cell is a predetermined threshold voltage.
